(19) United States
(12) Patent Application Publication
(10) Pub. No.: US 2014/0122964 A1
(43) Pub. Date: May 1, 2014

(54) ERROR CHECKING AND CORRECTION METHOD FOR DETERMINING AN ERROR CORRECTION CODE LENGTH AND RELATED ERROR CHECKING AND CORRECTION CIRCUIT

(71) Applicant: JMICRON TECHNOLOGY CORP., Hsin-Chu (TW)

(72) Inventor: Chao-Nan Chen, Hsinchu City (TW)

(73) Assignee: JMicron Technology Corp., Hsin-Chu (TW)

(21) Appl. No.: 13/798,185

(22) Filed: Mar. 13, 2013

(30) Foreign Application Priority Data
Oct. 30, 2012 (TW) 101140086

(51) Int. Cl. H03M 13/09

(52) U.S. Cl. CPC H03M 13/09
USPC 714/758

(57) ABSTRACT

A method of error checking and correction includes: performing compression upon an original data packet and generating a compressed data packet; determining an error correcting code length according to a data length; generating an error correcting code by performing error checking and correction encoding upon a packet data according to the error correcting code length; and combining the packet data and error correcting code into an encoded data packet. A method of error checking and correction includes: reading an encoded data packet, wherein the encoded data packet includes a packet data and an error correcting code, and the packet data includes a compressed data packet; generating a decoded compressed data packet corresponding to the compressed data packet by performing error checking and correction decoding upon the packet data according to the error correcting code; and performing decompression upon the decoded compressed data packet to generate a decompressed data packet.

### BACKGROUND OF THE INVENTION

1. Field of the Invention

The disclosed embodiments of the present invention relate to error checking and correction, and more particularly, to a method of error checking and correction for determining an error correction code length according to a data length, and a related circuit thereof.

2. Description of the Prior Art

The error correction code (ECC) is a conventional error correction technique which can be applied in a memory system such as a NAND flash. The error correction technique is used to check the correctness of data sent to the memory. When the system is transferring data, for example, an extra 1-bit parity code is added to an 8-bit data as a correction code. When an error occurs, the error checking and correcting code will be able to self-correct the error, or request the system to resend data. This ensures normal system operation without crashing due to data errors. Since this technique adds a debugging step, the operating speed of the ECC memory is slightly slower than the non-ECC memory. In addition, since the error correcting code (e.g. the parity code) is added to the ECC memory, operating bit length becomes longer (e.g. 72-bits instead of the conventional 64-bits) . This type of memory is usually used in high-end computers such as servers.

Conventionally, the error correction code is stored in a specific space indicated by the system, wherein the greater the space, the longer the length of the error correction code. This means that the performance of the error checking and correction function is improved. The specific space is a predetermined fixed length in conventional designs, which is not only inelastic, but also uses bandwidth inefficiently. Therefore, there is a need for an innovative error checking and correction design that can fully utilize bandwidth for enhancing the performance of the memory.

### SUMMARY OF THE INVENTION

One of the objectives of the present invention is to provide a method of error checking and correction for determining an error correction code length according to a data length, and a circuit thereof, to solve the above mentioned issues.

According to a first aspect of the present invention, a method of error checking and correction is disclosed. The method of error checking and correction comprises: performing data compression upon an original data packet and generating a compressed data packet; dynamically determining an error correcting code length according to a data length of the compressed data packet; generating an error correcting code by performing error checking and correction encoding upon a packet data according to the error correcting code length, wherein the packet data at least comprises the compressed data packet; and combining the packet data and the error correcting code into an encoded data packet.

According to a second aspect of the present invention, a method of error checking and correction is disclosed. The method of error checking and correction comprises: reading an encoded data packet, wherein the encoded data packet comprises a packet data and an error correcting code, and the packet data comprises at least a compressed data packet; generating a decoded compressed data packet corresponding to the compressed data packet by performing error checking and correction decoding upon the packet data according to the error correcting code; and performing data decompression upon the decoded compressed data packet to generate a decompressed data packet.

According to a third aspect of the present invention, a circuit of error checking and correction is disclosed. The circuit of error checking and correction comprises: a data compression circuit; a code length control circuit; an error correcting code encoder; and a packet generator. The data compression circuit is arranged to perform data compression upon an original data packet and generate a compressed data packet. The code length control circuit is arranged to dynamically determine an error correcting code length according to a data length of the compressed data packet. The error correcting code encoder is arranged to generate an error correcting code by performing error checking and correction encoding upon a packet data according to the error correcting code length, wherein the packet data at least comprises the compressed data packet. The packet generator is arranged to combine the packet data and the error correcting code into an encoded data packet.

According to a fourth aspect of the present invention, a circuit of error checking and correction is disclosed. The circuit of error checking and correction comprises: a packet parser; an error correcting code decoder; and a data decompression circuit. The packet parser is arranged to read an encoded data packet, wherein the encoded data packet comprises a packet data and an error correcting code, and the packet data comprises at least a compressed data packet. The error correcting code decoder is arranged to generate a decoded compressed data packet corresponding to the compressed data packet by performing error checking and correction decoding upon the packet data according to the error correcting code. The data decompression circuit is arranged to perform data decompression upon the decoded compressed data packet to generate a decompressed data packet.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a method of error checking and correction according to an exemplary embodiment of the present invention.

FIG. 2 is a diagram illustrating the step of dynamically determining an error correcting code length according to a data length of the compressed data packet.

FIG. 3 is another diagram illustrating the step of dynamically determining an error correcting code length according to a data length of the compressed data packet.

FIG. 4 is a diagram illustrating an error checking and correction circuit according to an exemplary embodiment of the present invention.

FIG. 5 is a diagram illustrating the code length control circuit of the error checking and correction circuit shown in FIG. 4 according to an embodiment of the present invention.

FIG. 6 is a diagram illustrating the code length control circuit of the error checking and correction circuit shown in FIG. 4 according to another embodiment of the present invention.

FIG. 7 is a diagram illustrating an error checking and correction circuit according to an exemplary embodiment of the present invention.

FIG. 8 is a diagram illustrating the error checking and correction circuit according to an exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ” . Also, the term “coupled” is intended to mean either an indirect or direct electrical connection. Accordingly, if one device is coupled to another device, that connection may be through a direct electrical connection, or through an indirect electrical connection via other devices and connections.

In the conventional memory access system, in order to solve the problem of data error, an appropriate error correcting code (ECC) is applied to detect and correct errors while performing data transmission. The receiving end can detect and correct transmission errors via examining encoded data. The error correction code checks the information stored in the memory electronically. Memories with error checking and correction functions are mainly for high-end PCs, servers or workstations. Subject to the limited bandwidth, a system usually limits a correction code (for example, a parity code) which is appended to data packets of a smaller length. The shorter the length of the correction code, the worse the performance of the error checking and correction function. The longer the length of the correction code, this represents that the bandwidth is sacrificed (i.e. the amount of data transfer decreases). The disclosed embodiments of the present invention enhance the performance of error checking and correction functions under a premise that the amount of data transfer is not affected. The detailed description is as follows.

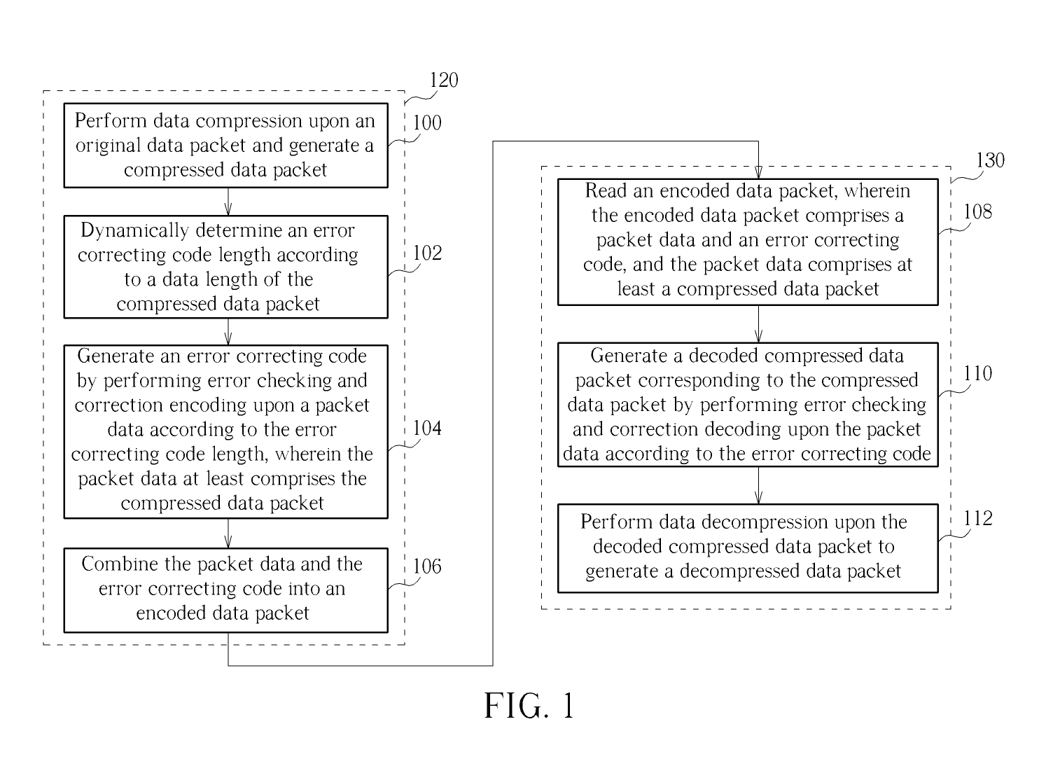

Please refer to FIG. 1, which is a flowchart illustrating a method of error checking and correction according to an exemplary embodiment of the present invention. Provided that substantially the same result is achieved, the steps of the flowchart shown in FIG. 1 need not be in the exact order shown and need not be contiguous; that is, other steps can be intermediate. Some steps in FIG. 1 may be omitted according to various types of embodiments or requirements. The method may be briefly summarized as follows:

Step 100: perform data compression upon an original data packet and generate a compressed data packet;

Step 102: dynamically determine an error correcting code length (e.g. a parity code length) according to a data length of the compressed data packet;

Step 104: generate an error correcting code (e.g. a parity code) by performing error checking and correction encoding upon a packet data according to the error correcting code length, wherein the packet data at least comprises the compressed data packet;

Step 106: combine the packet data and the error correcting code into an encoded data packet;

Step 108: read an encoded data packet, wherein the encoded data packet comprises a packet data and an error correcting code, and the packet data comprises at least a compressed data packet;

Step 110: generate a decoded compressed data packet corresponding to the compressed data packet by performing error checking and correction decoding upon the packet data according to the error correcting code; and

Step 112: perform data decompression upon the decoded compressed data packet to generate a decompressed data packet.

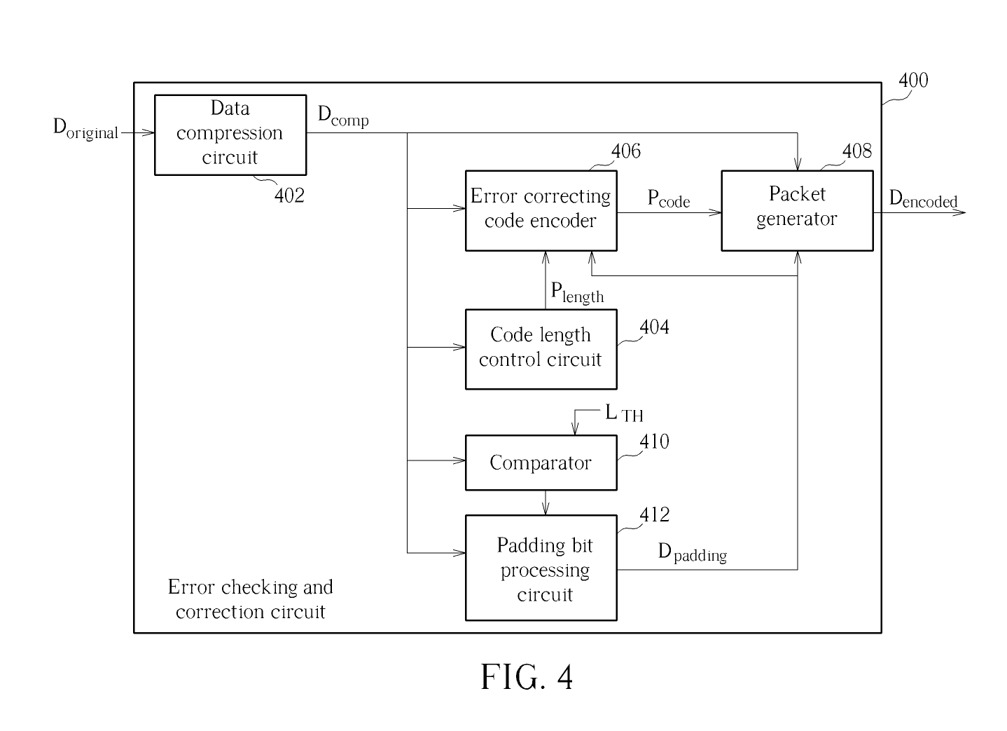

Please note that the steps 100-106 of the embodiment shown in FIG. 1 comprise a data write-in process 120, in which a data is written into a memory (e.g. a flash memory), and the steps 108-112 of the embodiment shown in FIG. 1 comprise a data read-out process 130, in which the data is read from the memory (e.g. a flash memory). With regards to the data write-in process 120, please also refer to FIG. 4, which is a diagram illustrating an error checking and correction circuit 400 according to an exemplary embodiment of the present invention. It should be noted that, in this embodiment, the error checking and correction circuit 400 is used to write data to a memory, and the error checking and correction circuit 400 includes a data compression circuit 402, a code length control circuit 404, an error correcting code encoder 406, a packet generator 408, a comparator 410, and a padding bit processing circuit 412. First, as shown in step 100, the data compression circuit 402 compresses an original data packet D_{original} to be written into the memory, and generates a compressed data packet D_{comp}. Please note that the focus of the present invention is to upgrade the performance of the error correction code without affecting the original data bandwidth and the correctness of the original data, thus the data compression process performed in step 100 (i.e. the data compression method of the data compression circuit 402) is a lossless data compression. Compared with the lossy data compression, the lossless data compression retains the data integrity. An original data packet and a data packet obtained from performing lossless data compression and corresponding lossless data decompression upon the original data packet are exactly the same. For instance, run-length encoding, Huffman, and Lempel Ziv algorithms are common lossless data compression methods; however, the present invention is not limited to any one of the above methods. In practice, any mechanism which performs lossless data compression can be applied to the data compression circuit 402.

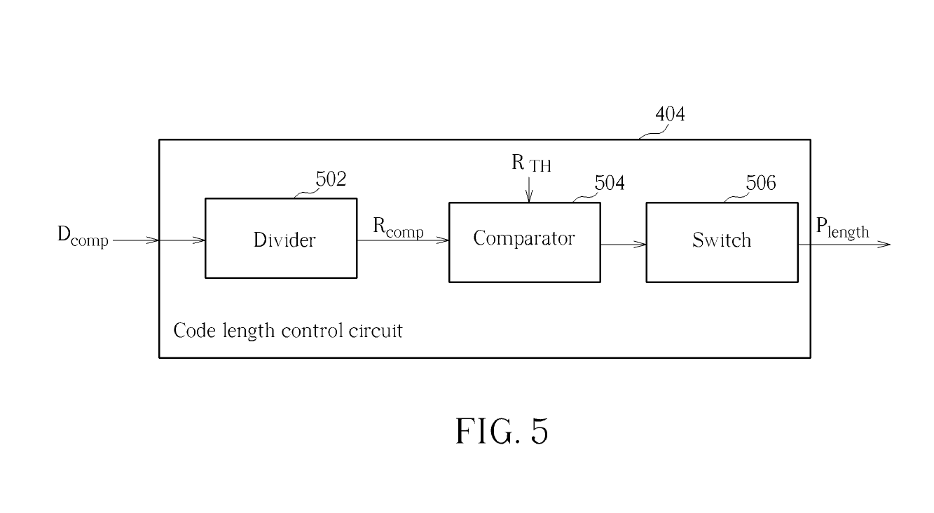

The compressed data packet D_{comp} generated after the data compression process has a data length, and the data length may vary from the content of the original data packet or the type of applied lossless data compression algorithm. The compression rate R_{comp} of the compressed data packet D_{comp} cannot be known before the data compression process is done, but the compression rate R_{comp} of the compressed data packet D_{comp} needs to be computed after the data compression process is done. In this embodiment, the step 102 is accomplished by the code length control circuit 404 shown in FIG. 4. Please refer to FIG. 5, which is a diagram illustrating the code length control circuit 404 of the error checking and correction circuit 400 shown in FIG. 4 according to an embodiment of the present invention. In this embodiment, the code length control circuit 404 includes a divider 502, a comparator 504, and a switch 506. First, the divider 502 divides the data length of the compressed data packet D_{comp} by a data length of the original data packet D_{original}, to obtain the above mentioned compression rate R_{comp} corresponding to the original data packet D_{original}. The smaller the compression rate R_{comp}, the greater the extent of the original data packet D_{original} being compressed; therefore, the more the empty space can be utilized. Next, the comparator 504 compares the compression rate R_{comp} and a specific compression rate R_{TH}. If the compression rate R_{comp} is not less than the specific compression rate R_{TH}, then the switch 506 sets an error correcting code length P_{length} of a parity code P_{code} of the corresponding compressed data packet D_{comp} to a first value D1. If the compression rate R_{comp} is less than the specific compression rate R_{TH}, then the switch 506 sets an error correcting code length P_{length} of a parity code P_{code} of the corresponding compressed data packet D_{comp} to a second value D2, wherein the second value D2 is greater than the first value D1 (i.e., D2>D1) . Therefore, the error correcting code length P_{length} may be dynamically switched to a first value D1 or a second value D2 according to the data compression result of the content of the original data packet D_{original}. Specifically, the focus of the present invention is to exploit the limited bandwidth for increasing the error correcting code length P_{length} to protect the data or packets that need to be transferred, instead of using a fixed error correcting code length as the convention mechanism. Due to the characteristics of the error correction code, the error correcting code length P_{length} with arbitrary length may not be suitable for a real design. Therefore, the error correcting code length P_{length} with two-stage length transformation is disclosed in this embodiment: the error correcting code length P_{length} may be switched between two different lengths dynamically according to the data compression result of the content of the original data packet. A plurality of different specific compression ratio may also be set to define a plurality of stages of length transformation (e.g. more than two stages), and the compression rate R_{comp} is compared with each specific compression rate by the comparator 504, for detecting in which stage the compression rate R_{comp} falls. The switch 506 may dynamically switch between different correction code lengths according to a comparison result of the comparator 504. The alternative design also belongs to the scope of the present invention.

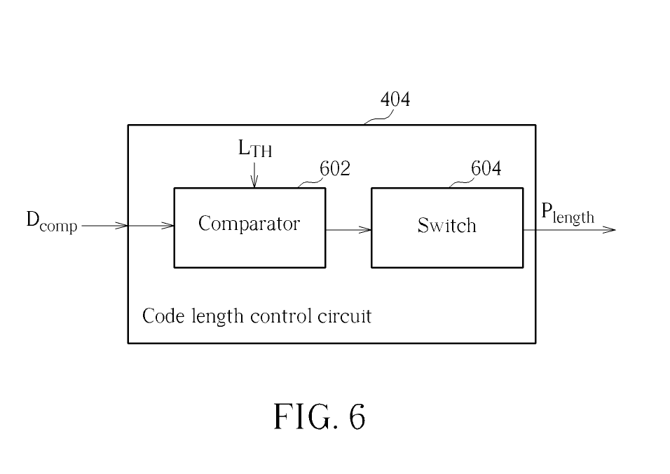

Please note that determining the error correcting code length via compression rate is for illustrative purposes only, but is not a limitation. Please refer to FIG. 6, which is a diagram illustrating the code length control circuit 404 of the error checking and correction circuit 400 shown in FIG. 4 according to another embodiment of the present invention. In this embodiment, the code length control circuit 404 includes a comparator 602, and a switch 604. First, the comparator 602 compares the length of the compressed data packet D_{comp} and a predetermined data length L_{TH}. Next, the switch 604 sets the error correcting code length P_{length} to a first value D1 or a second value D2 selectively according to the comparison result generated from the comparator 602, wherein the second value D2 is greater than the first value D1 (i.e., D2>D1). Similarly, a plurality of different predetermined data length may also be set to define a plurality of stages of length transformation (e.g. more than two stages), and the length of the compressed data packet D_{comp} is compared with each predetermined data length by the comparator 602 for detecting in which stage the length of the compressed data packet D_{comp} falls. The switch 604 may switch between different correction code lengths dynamically according to a comparison result of the comparator 602. This alternative design also belongs to the scope of the present invention.

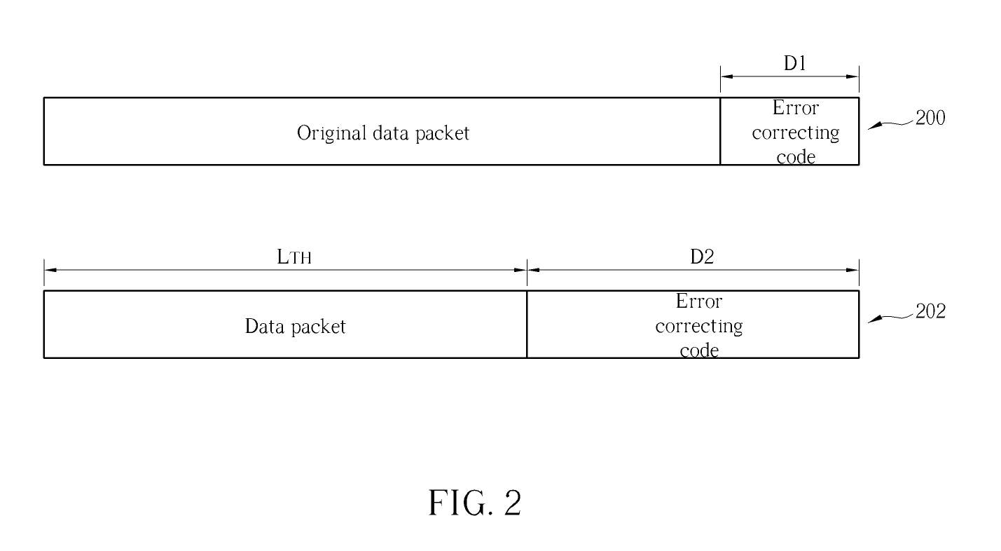

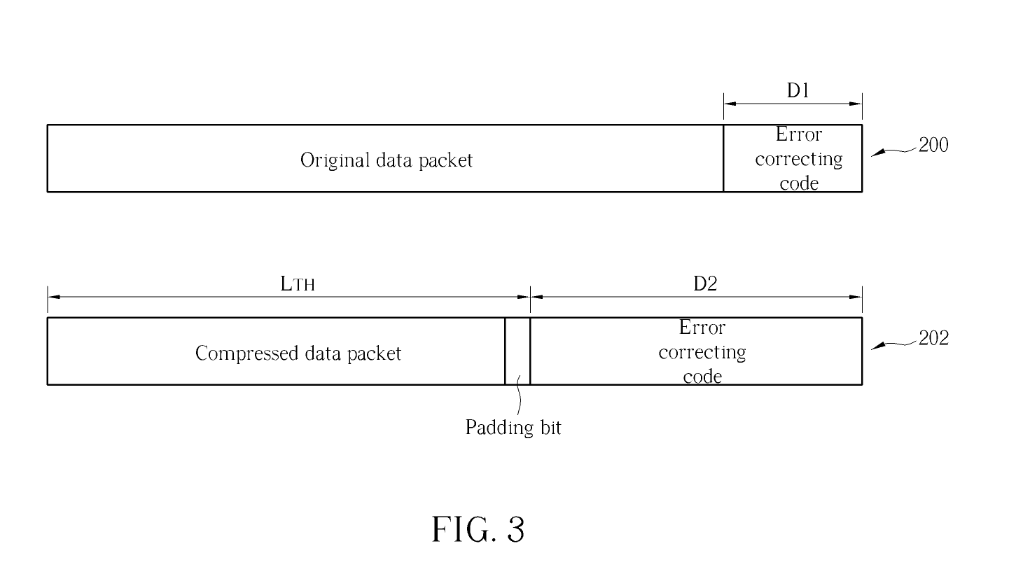

Please refer to FIG. 2 and FIG. 3, which are diagrams illustrating the step of dynamically determining an error correcting code length according to a data length of the compressed data packet. The length of a data packet in FIG. 2 is the predetermined data length L_{TH}, and the error correcting code length P_{length} of a corresponding error correction code 202 is the second value D2. Hence, the corresponding error correcting code length P_{length} of the compressed data packet D_{comp} which is shorter than the predetermined data length L_{TH} is set to the second value D2. The corresponding error correcting code length P_{length} of the compressed data packet D_{comp} which is not shorter than the predetermined data length L_{TH} is set to the first value Dl. It should be noted that, in this exemplary embodiment, the first value D1 is the length of the error correction code 200 corresponding to the original data packet. Similarly, as described above, a plurality of error correction codes lengths may also be used for the corresponding specific compression rates: for instance, 4 compression rates, such as 0.25, 0.5, 0.55, and 1 may be used to divide the entire compression ratio (i.e. compression rate 0˜compression rate 1) into four sections (i.e. 0˜0.25, 0.25˜0.5, 0.5˜0.55, and 0.55˜1), and the corresponding error correction code lengths are 868 bytes, 616 bytes, 350 bytes, and 112 bytes. It should be noted that the method of selecting the specific compression rate and the number of the specific compression rate is not limited to the above examples; it should be configured according to actual usage, and the compression method or algorithm may also affect selection of the specific compression rate. Regardless of whether the error correction code length is switched dynamically or an error correction code corresponding to a constant compression rate is used, both embodiments belong to the scope of the present invention. Regardless of the number of compression rate segments (i.e. the number of specific compression rates), all modifications belong to the scope of the present invention.

The length of the compressed data packet D_{comp} may not exactly equal the predetermined data length L_{TH} shown in FIG. 2, but usually there will be empty space with a few bytes length. In step 104, before generating the parity code P_{code}, a comparator 410 in the error checking and correction circuit 400 compares the length of the compressed data packet D_{comp} and the predetermined data length L_{TH} to determine a padding bit length. Then a padding bit processing circuit 412 may be used to append predetermined padding bits (e.g. the value of the predetermined padding bit may be 0 or 1) to the empty space (with a few bytes length) shown in FIG. 3 for generating the packet data. The error correcting code encoder 406 can use the packet data to generate the parity code P_{code}. In the data write-in process 120 of this embodiment, a packet generator 408 in the error checking and correction circuit 400 is used to combine the compressed data packet D_{comp}, the padding bits, the parity code P_{code}, the information of the error correcting code length P_{length}, and the information of the padding bit length (the information of the error correcting code length P_{length}, and the information of the padding bit length are not shown in FIG. 4) into an encoded data packet (i.e. step 106). Please note that the information of the padding bit length may not be appended to the encoded data packet; in this case, the corresponding read-out process will be described as follows.

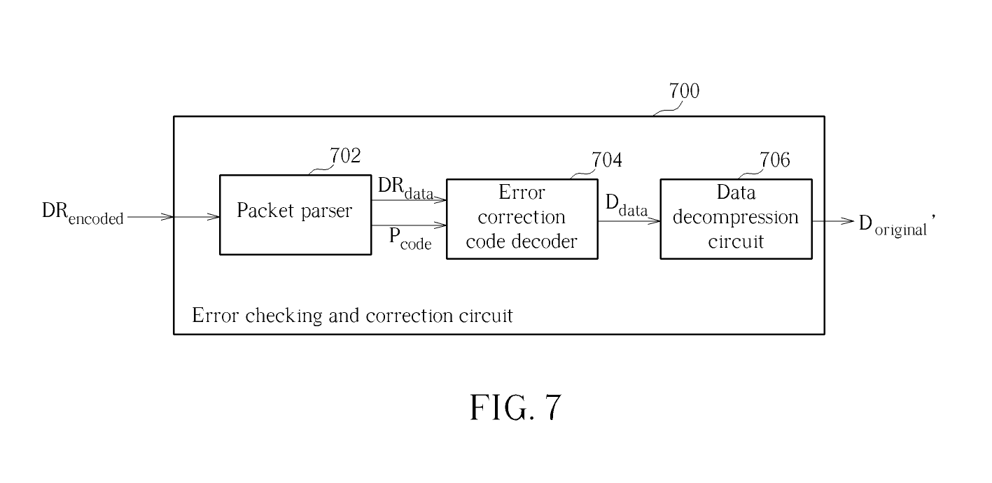

With regards to the data read-out process 130, please also refer to FIG. 7, which is a diagram illustrating an error checking and correction circuit 700 according to an exemplary embodiment of the present invention. It should be noted that, in this embodiment, the error checking and correction circuit 700 is used to read data (e.g., the encoded data packet D_{encoded} written from the error checking and correction circuit 400 to the memory) from a memory (e.g. a flash memory), and the error checking and correction circuit 700 includes a packet parser 702, an error correction code decoder 704, and a data decompression circuit 706. First, as shown in step 108, the packet parser 702 parses out the error correcting code length P_{length} of the parity code P_{code} and the information of the padding bit length mentioned above from an encoded data packet DR_{encoded}. Next, the parity code P_{code} and a packet data DR_{data} according to the error correcting code length P_{length} of the parity code P_{code} are retrieved. It should be noted that, compared to the encoded data packet D_{encoded} in FIG. 4, there may be error bits in the encoded data packet DR_{encoded} in FIG. 7 due to the interference of the channel noise or the corruption of the memory itself. Hence, compared to the packet data DR_{data} shown in FIG. 4, there may be error bits in the packet data DR_{data} shown in FIG. 7, and this is the reason for the error checking and correction circuit.

After parsing out the packet data DR_{data}, the parity code P_{code}, and the information of the padding bit length, the error correction code decoder 704 performs error checking and correction decoding upon the packet data DR_{data} according to the parity code P_{code}. Therefore, the error correction code decoder 704 may detect and correct error bits in the packet data DR_{data} via the parity code P_{code}, and generate a decoded compressed data packet D_{data} corresponding to the compressed data packet D_{comp} mentioned above (i.e. step 110) . Next, the data decompression circuit 110 of the error checking and correction circuit 700 in FIG. 7 performs data decompression upon the decoded compressed data packet D_{data}, i.e. step 112 shown in FIG. 1, and generates a decompressed data packet D_{original′}. In this embodiment, the data decompression process performed by the data decompression circuit 110 of the error checking and correction circuit 700 corresponds to the data compression process performed by the data compression circuit 402 of the error checking and correction circuit 400, and is also lossless data decompression. For instance, if the data compression process performed by the data compression circuit 402 of the error checking and correction circuit 400 is based on a run-length encoding algorithm, then a data decompression process performed by the data decompression circuit 110 of the error checking and correction circuit 700 is also based on the run-length encoding algorithm. However, the lossless data decompression method of the present invention is not limited to the run-length encoding algorithm. In practice, any mechanism which performs lossless data decompression can be applied to the data decompression circuit 110. It should be noted that the decoded compressed data packet D_{data} includes the compressed data packet D_{comp} and the padding bits mentioned above; however, the length of the decompressed data packet D_{original} is fixed and known, hence the decoded compressed data packet D_{data} may be decompressed bit by bit till the data length outputted from the data compression circuit 402 of the error checking and correction circuit 400 equals the length of the decompressed data packet D_{original}. The padding bits appended to the compressed data packet D_{comp} can be ignored without being processed. Please note that if all the error bits can be corrected according to the parity code P_{code}, then the data contents of the decompressed data packet D_{original} and the original data packet D_{original} are the same.

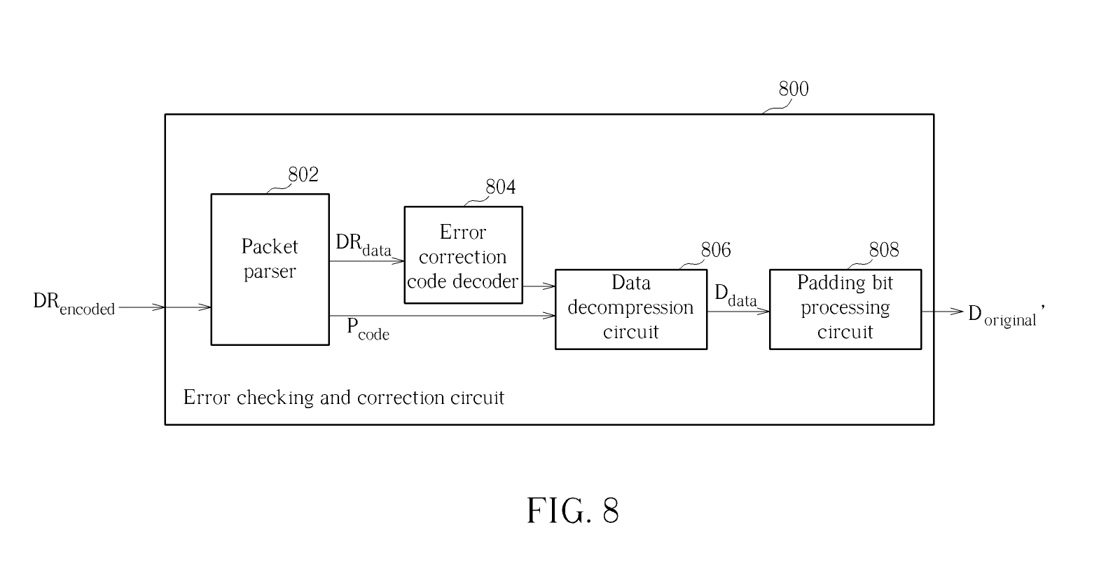

Please refer to FIG. 8, which is a diagram illustrating the error checking and correction circuit 800 according to an exemplary embodiment of the present invention. In regards to the data read-out process 130 shown in FIG. 1, it is also practicable to employ the error checking and correction circuit 800 shown in FIG. 8 to obtain the desired decompressed data packet D_{original′} from the encoded data packet DR_{encoded}. In this embodiment, the padding bit processing 804 processes the padding bits appended to the compressed data packet D_{comp} for enhancing the performance and debugging ability of the present invention. First, the padding bit processing 804 checks the padding bits of the packet data DR_{data} according to the information of the padding bit length generated from the packet parser 702, since the padding bits are known bits (e.g. bit “0” orbit “1”) . It can determine if there are any error padding bits in the packet data DR_{data} according to the information of the padding bit length. If there are error bits in the packet data DR_{data}, the error bits can be corrected directly without being corrected by the error correcting code decoder 806, which saves the available amount of the correctable error bits. For instance, if the length of the error correction code corresponds to 40 correctable bits, there is a total of 41 error bits in the received packet data DR_{data,} wherein 1 error bit is located in the range of the padding bits of the packet data DR_{data}, and the other 40 error bits are in the range of the compressed data packet D_{comp}. Under the condition that the 1 error bit of the padding bits is not corrected in advance, the entire encoded data packet DR_{encoded} will be abandoned since the number of total error bits exceeds the number of correctable error bits. In this embodiment, the 1 error padding bit in the packet data DR_{data} can be corrected directly via the padding bit processing circuit 804 without being corrected by the error correcting code decoder 806. This decreases the total error bit number of the packet data DR_{data} to 40. Therefore, the following error correcting code decoder 806 can successfully correct all 40 error bits, and the packet data DR_{data} can be correctly recovered to the original data packet D_{original} (i.e. the original data packet D_{original}=the decompressed data packet D_{original′}). In addition, the operation principles of other components of the error checking and correction circuit 800 (i.e. the packet parser 802, the error correction code decoder 804, and the data decompression circuit 806) are similar to the components in the error checking and correction circuit 800 with the same name, and are omitted here for brevity.

The present invention not only fully utilizes the extra bandwidth obtained via lossless data compression for error checking and correction process, but also utilizes the remaining padding bits to further improve the accuracy of error checking and correction process, which reduces the system loading and latency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of error checking and correction, comprising:
performing data compression upon an original data packet and generating a compressed data packet;
dynamically determining an error correcting code length according to a data length of the compressed data packet;
generating an error correcting code by performing error checking and correction encoding upon a packet data according to the error correcting code length, wherein the packet data at least comprises the compressed data packet; and
combining the packet data and the error correcting code into an encoded data packet.

2. The method of claim 1, wherein the method of error checking and correction is applied in a memory access system.

3. The method of claim 1, wherein the data compression performed upon the original data packet is a lossless data compression.

4. The method of claim 1, wherein the step of determining an error correcting code length according to a data length of the compressed data packet dynamically comprises:
dividing the data length of the compressed data packet by a data length of the original data packet, to obtain a compression rate corresponding to the original data packet; and
dynamically determining the error correcting code length according to the compression rate.

5. The method of claim 4, wherein the step of dynamically determining an error correcting code length according to a data length of the compressed data packet comprises:
comparing the compression rate and a specific compression rate;
when the compression rate is not less than the specific compression rate, setting the error correcting code length to a first value; and
when the compression rate is less than the specific compression rate, setting the error correcting code length to a second value, wherein the second value is greater than the first value.

6. The method of claim 1, wherein the step of dynamically determining an error correcting code length according to a data length of the compressed data packet comprises:
comparing the data length of the compressed data packet and a predetermined data length;
when the data length is not less than the predetermined data length, setting the error correcting code length to a first value; and
when the data length is less than the predetermined data length, setting the error correcting code length to a second value, wherein the second value is greater than the first value.

7. The method of claim 1, further comprising:
adding the information of the error correcting code length into the encoded data packet.

8. The method of claim 1, further comprising:
determining a padding bit length by comparing the data length of the compressed data packet and a predetermined data length; and
appending padding bits to the compressed packet according to the padding bit length, to generate the packet data.

9. The method of claim 1, further comprising:
adding the information of the padding bit length into the encoded data packet.

10. A method of error checking and correction, comprising:
reading an encoded data packet, wherein the encoded data packet comprises a packet data and an error correcting code, and the packet data comprises at least a compressed data packet;
generating a decoded compressed data packet corresponding to the compressed data packet by performing error checking and correction decoding upon the packet data according to the error correcting code; and
performing data decompression upon the decoded compressed data packet to generate a decompressed data packet.

11. The method of claim 10, wherein the method of error checking and correction is applied in a memory access system.

12. The method of claim 10, wherein the data compression performed upon the original data packet is a lossless data compression.

13. The method of claim 10, wherein the encoded data packet further comprises the information of an error correcting code length of the error correcting code, and the method further comprises:
obtaining the error correcting code in the encoded data packet according to the error correcting code length.

14. The method of claim 10, wherein the encoded data packet further comprises the information of a padding bit length, and the method further comprises:
examining padding bits appended to the packet data according to the padding bit length.

15. A circuit of error checking and correction, comprising:
a data compression circuit, arranged to perform data compression upon an original data packet and generate a compressed data packet;
a code length control circuit, arranged to dynamically determine an error correcting code length according to a data length of the compressed data packet;
an error correcting code encoder, arranged to generate an error correcting code by performing error checking and correction encoding upon a packet data according to the error correcting code length, wherein the packet data at least comprises the compressed data packet; and
a packet generator, arranged to combine the packet data and the error correcting code into an encoded data packet.

16. The circuit of claim 15, wherein the circuit of error checking and correction is applied in a memory access system.

17. The circuit of claim 15, wherein the data compression performed upon the original data packet is a lossless data compression.

18. The circuit of claim 15, wherein the code length control circuit comprises:
a divider, arranged to divide the data length of the compressed data packet by a data length of the original data packet, to obtain a compression rate corresponding to the original data packet; and
a selection circuit, arranged to dynamically determine the error correcting code length according to the compression rate.

19. The circuit of claim 18, wherein the selection circuit comprises:
a comparator, arranged to compare the compression rate and a specific compression rate;
a switch, arranged to set the error correcting code length to a first value or a second value selectively according to the compression rate and the specific compression rate, wherein the second value is greater than the first value.

20. The circuit of claim 15, wherein the code length control circuit comprises:
a comparator, arranged to compare the data length of the compressed data packet and a predetermined data length;
a switch, arranged to set the error correcting code length to a first value or a second value selectively according to the data length and the predetermined data length, wherein the second value is greater than the first value.

21. The circuit of claim 15, wherein the packet generator further adds the information of the error correcting code length into the encoded data packet.

22. The circuit of claim 15, further comprising:
a comparator, arranged to determine a padding bit length by comparing the data length of the compressed data packet and a predetermined data length; and
a padding bit processing circuit, arranged to append padding bits to the compressed packet according to the padding bit length, to generate the packet data.

23. A circuit of error checking and correction, comprising:
a packet parser, arranged to read an encoded data packet, wherein the encoded data packet comprises a packet data and an error correcting code, and the packet data comprises at least a compressed data packet;
an error correcting code decoder, arranged to generate a decoded compressed data packet corresponding to the compressed data packet by performing error checking and correction decoding upon the packet data according to the error correcting code; and
a data decompression circuit, arranged to perform data decompression upon the decoded compressed data packet to generate a decompressed data packet.

24. The circuit of claim 23, wherein the circuit of error checking and correction is applied in a memory access system.

25. The circuit of claim 23, wherein the data compression performed upon the original data packet is a lossless data compression.

26. The circuit of claim 23, wherein the encoded data packet further comprises the information of an error correcting code length of the error correcting code, and the packet parser is further arranged to obtain the error correcting code in the encoded data packet according to the error correcting code length.

27. The circuit of claim 23, wherein the encoded data packet further comprises the information of a padding bit length, and the circuit further comprises:
a padding bit processing circuit, arranged to examine padding bits appended to the packet data according to the padding bit length.
